(19) United States
(12) Patent Application Publication
(10) Pub. No.: US 2025/0234492 A1
(43) Pub. Date: Jul. 17, 2025

(54) ELECTRIC COMPONENT WITH IMPROVED COOLING AND CORRESPONDING MODULE

(71) Applicant: TDK EUROPE GMBH, München (DE)

(72) Inventor: Shinichiro Nishizawa, Muenchen (DE)

(21) Appl. No.: 18/690,919

(22) PCT Filed: Sep. 14, 2022
(86) PCT No.: PCT/EP2022/075512

§ 371 Date: Mar. 11, 2024

(30) Foreign Application Priority Data
Sep. 14, 2021 (DE) 102021123731.9

(51) Int. Cl. H05K 7/20

(52) U.S. Cl. CPC H05K 7/2039

(57) ABSTRACT

In an embodiment an electric component includes an electric element with an underside and a lead at the underside and a cooling element comprising an underside, wherein the cooling element is arranged below the electric element, and wherein the cooling element is a heat bridge configured to conduct heat from the underside of the electric element to the underside of the cooling element and/or from the lead to the underside of the cooling element.

### CROSS-REFERENCE TO RELATED APPLICATIONS

This patent application is a national phase filing under section 371 of PCT/EP2022/075512, filed Sep. 14, 2022, which claims the priority of German patent application 102021123731.9, filed Sep. 14, 2021, each of which is incorporated herein by reference in its entirety.

### TECHNICAL FIELD

The present invention refers to electric components with improved cooling and to corresponding modules comprising one or more such electric components.

### BACKGROUND

Electric modules comprise electric components in electric circuits. Electric currents in the electric components lead to energy dissipation and thus to heating of the electric components. For example in a DC link capacitor currents, specifically ripple currents, lead to temperature increases during operation of the corresponding modules. Temperature increase of electric components can reduce the components' lifetime or even lead to sudden destruction of the components. Further, temperature increases can lead to deteriorated electric performance.

Typically, electric components of a module are electrically connected to one another to establish electrical circuits. The corresponding components can be arranged on a circuit board, e.g. a printed circuit board (PCB) with electrical connectors structured in metallization layers on the surface of the circuit board. A conventional means for temperatures of electrical components is to cascade a plurality of electrical components such that currents are distributed over a larger number of components, reducing the stress of each individual electrical component. However, cascading of electrical elements, e.g. in series or in parallel, leads to an increased area consumption on the circuit board and to increased manufacturing costs.

Another possibility to reduce the thermal stress of an electrical component is to arrange a thermal paste material between the underside of the electrical component and the topside of the corresponding circuit board. However, thermal paste has a certain electrical conductivity and the application of thermal paste reduces the design flexibility of the circuit board and the design flexibility of electrical connection between the electric component and the circuit board. Further, the thermal performance of thermal paste is time-dependent and the thermal performance of thermal paste can degrade over time. Further, the performance of thermal paste depends on the actual geometric connection (adhesion) between the component, the paste and the circuit board. The later check of the application of thermal paste, however, is difficult after mounting the electrical component on the circuit board.

From WO 21/111004 A1 electric inverter modules with a first PCB mounted on a heatsink and capacitors positioned on the first PCB are known.

### SUMMARY

Embodiments provide electric components and corresponding modules with a reduced need for area on a circuit board and with increased performance that can be manufactured at lower manufacturing costs. Further embodiments provide increased design flexibility when designing the conductor patterns of a printed circuit board and provide electric components with an increased lifetime and a reduced probability of failure.

The electric component with improved cooling comprises an electric element. The electric element has an underside and one or more leads at the underside. Further, the electric component comprises a cooling element. The cooling element comprises an underside. Further, the cooling element is arranged below the electric element. The cooling element is a heat bridge that is provided to and adapted to conduct heat from the underside of the electric element to the underside of the cooling element and/or from the lead to the underside of the cooling element.

The electric element or the electric component comprising the electric element may be a surface-mountable component that can be electrically and mechanically connected in a SMT-type manner to a circuit board (SMT=surface mount technology). To that end the lead of the electric element can be realized as a metallic protrusion protruding from the underside of the electric element that is adapted and configured to electrically and mechanically connect the electric component to corresponding sides on the circuit board.

The number of leads is not limited to one. The electric component and the electric element of the electric component, respectively, can comprise a second lead and one or more additional leads. However, a preferred number of leads is two or three. Then two of the leads can be used to electrically connect electrodes of the electric element to an external circuit element of the circuit board. A third lead can be used to electrically connect a ground potential of the electric element to a ground potential of the circuit board.

The cooling element establishes a heat path where heat deriving from the activity of the electric element can propagate via the cooling element to the underside of the cooling element and where the heat can then be transferred to corresponding structures of the circuit board.

At first glance, the provision of the cooling element establishes a further series element in the heat path from the electric element to a corresponding circuit board. In general, the provision of an additional series element increases the resistivity of the heat flow from the electric element to the circuit board. Thus, it would be expected that by providing an additional element between the electric element and a circuit board, the corresponding heat flow would be reduced and an operation temperature of the electric element would be higher compared to the situation without the cooling element.

However, it was found that instead the electric element can be operated with a reduced operation temperature due to the fact that the cooling element does not establish a series element in the heat flow but a parallel element in the heat flow. Thus, by thermally coupling the cooling element to the underside of the electric element and/or to the one or more leads of the electric element, an additional heat flow path is provided compared to the situation where essentially the whole heat must propagate via the leads from the electric element circuit.

To augment the provision of further parallel heat paths, the cooling element can comprise internal heat conduction structures are thermally built into the underside of the electric element or to the leads of the electric element.

It has been found that the effect of the improved cooling of such an electric component is that the components can be operated at lower temperatures. As a consequence thereof, the number of electrical components can be reduced because a cascading is necessary to a lesser extent compared to the situation without cooling elements. Thus, the area consumption on a circuit board is reduced, manufacturing costs are reduced, the reliability is increased due to the lower number of elements that can potentially fail and because the heat flow is improved flexibility for designing the surface of the corresponding sides on the circuit board is also increased. Specifically, the number of components necessary for the same electric functionality can be reduced thus that the overall costs can be reduced, despite the additionally provided cooling element.

It is possible that the footprint of the cooling element is smaller than or equal to the footprint of the electric element of the electric component.

Thus, there is essentially no additional area consumption on the circuit board.

The additional provision of the cooling element may increase the overall height of the electric component compared to the overall height of an electric element. However, the significant reduction of thermal stress and the necessity to use a plurality of cascaded elements can easily outweigh the small increase in height.

It is possible that the cooling element has a layered structure.

The layered structure of the cooling element can comprise specifically tailored thermal conduction paths that establish parallel conduction paths such that the overall resistance to the heat flow is reduced. The layered structure can comprise horizontally aligned heat paths of a material with a high thermal conductivity.

Specifically, it is possible that the layered structure comprises a high thermal conduction layer and a dielectric layer. The thermal conductivity of the high conduction layer is larger than the thermal conductivity of the dielectric layer.

Thus, the provision of the high thermal conduction layer provides an additional parallel heat flow path reducing the overall heat flow resistance.

The provision of a dielectric material in the dielectric layer ensures the necessary electrical separation of different electric potentials such that short circuits are prevented. The dielectric material can therefore be selected, adapted and provided to electrically separate high voltage contacts of the electric element. Electrical separation of voltages such as 10 V, 50 V, 100 V, 200 V, 500 V, 1000 V, 2000 V or even more can be provided.

Further, it was found that electrically conductive materials usually have a high thermal conductivity too. Thus, materials that are also electrical conductors are suitable for the high thermal conduction layer. Thus, the provision of the dielectric material ensures the corresponding electric isolation between corresponding electrical contacts.

The number of high thermal conduction layers and the number of dielectric layers is not limited. The number of high thermal conduction layers can be 1, 2, 3, 5, 6, 7, 9, 10 or more. Also, the number of dielectric layers can be 1, 2, 3, 4, 5, 6. 7, 9, 10 or more.

It is possible that the high thermal conduction layer comprises or consists of a material selected from a crystalline material, a ceramic material, an aluminum oxide, Alumina (Al2O3), a metal, gold, silver, copper, Aluminum Nitride (AlN), Beryllium Oxide (BeO).

Further, it is possible that the dielectric layer or the plurality of dielectric layers comprise or consist of a dielectric material selected from a crystalline material, a ceramic material, an aluminum oxide, Al2O3, an organic material, a PCB material, FR4, Getek, Megtron, 4000-13, FR-408.

Further, it is possible that the one or more leads comprise or consist of an electrically conducting material selected from a metal, gold, silver, copper.

Further, it is possible that the electric component comprises a top and a side. Further, the electric component comprises one or more cooling fins that are arranged at the top and/or at the side of the electric component.

As the cooling element provides a first additional shunt path for a heat flow from the electric element towards the electric element surroundings, heat fins establish further shunt paths for heat flow from the electric element to the surroundings.

Thus, by providing additional heat fins, the operation temperatures of the electric element can be further reduced. In this respect, it is possible that the heat fins at the side of the electric component are arranged at the side of the electric element and/or the side of the cooling element. Further, it is possible that an underside of the cooling element also has heat fins for an increased heat flow to the surroundings of the electric component.

However, it may be preferred that the underside of the cooling element is directly attached to the topside of the circuit board or to a thermal paste pad between the underside of the cooling element and the topside of the circuit board.

It is possible that the electric component further comprises a first additional thermal conduction layer arranged between the electric element and the cooling element and/or a second additional thermal conduction layer arranged at the underside of the cooling element.

The first additional thermal conduction layer can be provided to improve the thermal coupling between the electric element and the cooling element. The second additional thermal conduction layer can be provided to improve the thermal coupling between the cooling element and a topside of a circuit board.

It is possible that the first and/or second additional thermal conduction layers comprise or consist of a material selected from a thermal solid/liquid paste (including epoxies, silicones, urethanes, and/or acrylates)

It is possible that the electrical element is selected from a passive circuit element, a capacitance element, a paper/film/Ceramic capacitance element, an electrolyte capacitor, a Y-glass capacitor, a resistance element, a diode, a sensor, an active circuit element, a switch, an element with an integrated circuit, a processor, a semiconductor element, a light-emitting diode (LED).

In this respect, a Y-glass capacitor is a capacitor that complies with more stringent security requirements necessary in some electric components or modules.

It is possible that the height of the cooling element is larger than or equal to 0.1 mm and smaller than or equal to 5 mm. Further or additionally, it is possible that the cooling element has a layered structure with 1, 2, 3, 4, 5, 6, 7, 8, 9 or more stacked layers.

However, it is also possible that the cooling element comprises a thermal conduction layer TCM, a dielectric material and/or an electrically conductive material in a single layer construction.

As stated above, the added overall height of the electric component caused by the provision of the cooling element below the electric element is more than compensated by the reduction of area consumption and the reduced operating temperatures.

Correspondingly, a module can comprise a circuit board and an electric component as described above. The cooling element of the electric component or the second additional thermal conduction layer is arranged on the circuit board.

In this respect it is preferred that the cooling element is thermally coupled, e.g. via the thermal conduction layer if present-to the circuit board to increase the heat flow from the electric element to the circuit board.

Further, it is possible that the module comprises via connections for a ground connection. Thus, the module comprises ground vias in the circuit board. The ground vias in the circuit board can be thermally coupled to the underside of the cooling element, specifically to high thermal conduction structures of the cooling element.

Further, it is possible that the module additionally comprises a base plate where the circuit board is arranged at the base plate or mechanically connected to the base plate. The circuit board can be mechanically connected to the base plate via screws and the screws can thermally couple the cooling element, e.g. via ground connections in the circuit board, to the base plate.

Thus, an improved cooling solution for electric elements without the need for additional surface area but with the possibility of reducing the area consumption of a circuit board is provided. The cooling of the electric element is provided despite the provision of an additional element between the element to be cooled and the corresponding circuit board.

The electric component can be used to provide a film capacitor to an external circuit environment, e.g. for EMC measures (EMC=electromagnetic compatibility), specifically, but not limited to, the electric component, can be used in a DC link circuit configuration where a capacitor is arranged between inverters connected to a battery and an electric motor.

The electric component can be used in high voltage applications up to several thousand volts operation voltage. The provision of the cooling element ensures the compliance with limited operation temperatures.

When the electric element of the electric component is a capacitance element, then the capacitance of the capacitance element can be in the range between 10 pF and 10 nF.

The cooling element can have the effect that operation temperatures are reduced by 70 K. It is possible that a reduction of operation temperatures of 10 K doubles the expected lifetime. Thus a more than hundredfold lifetime increase is possible.

Further, due to the reduced operation temperatures, linearity of the electric properties of the electric element can be increased and the electric performance of corresponding modules can be substantially improved.

### BRIEF DESCRIPTION OF THE DRAWINGS

Central aspects of the electric component and details of preferred embodiments are shown in the accompanying schematic figures.

FIG. 1 shows the provision of additional parallel heat paths of the cooling element;

FIG. 2 shows the integration of a corresponding electric component in a module via a circuit board;

FIG. 3 shows the possibility of additional thermal conduction layers;

FIG. 4 illustrates a cross-section through a cooling element showing a plurality of stacked layers;

FIG. 5 illustrates the application of the layered structure of the cooling element between the electric element and a circuit board;

FIG. 6 shows a possible heat flow distribution for a specific layer construction;

FIG. 7 shows the possibility of applying cooling fins to the outer periphery of the component;

FIG. 8 shows a perspective view of a capacitor with added cooling element and a detached set of cooling fins;

FIG. 9 shows the increase of lifetime expectancy via a temperature reduction; and

FIG. 10 illustrates the effectiveness of the cooling solution provided by the cooling element.

### DETAILED DESCRIPTION OF ILLUSTRATIVE EMBODIMENTS

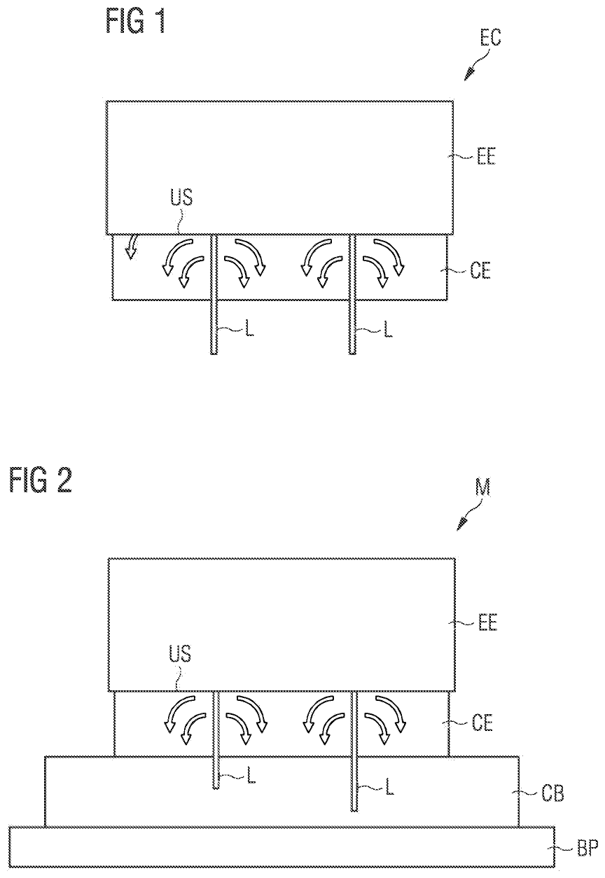

FIG. 1 shows the relation between the electric element EE of an electric component EC and the cooling element CE of the electric component EC. The electric element EE has an underside US and leads L protruding from the underside US. At the underside US of the electric element EE the cooling element CE is attached such that the leads L are led through the cooling element CE and protrude from the underside US of the cooling element CE. The cooling element CE is thermally coupled to the underside US of the electric element EE and/or to the leads L of the electric element EE. When no cooling element CE would be present, then heat could be conducted to the surroundings of the electric component EC via the leads L and via the underside US surface of the electric component EC. However, the provision of the cooling element CE provides additional heat paths HP within the cooling element CE. The heat paths HP can conduct heat from the underside US of the electric element EE or from the leads L of the electric element EE to an external environment with a reduced thermal resistivity such that the overall heat flow from the electric element EE to the surroundings is increased. As a consequence thereof, operation temperatures of the electric element EE of the electric component EC are substantially reduced. As a result thereof lifetime is increased and cascading of corresponding elements is only required to a lesser degree. The footprint of the cooling element CE is preferably not larger than the footprint of the electric element EE such that the placement of corresponding electric components next to other components can be applied with conventional tools and without additional effort.

FIG. 2 illustrates the possibility of connecting the electric component comprising the cooling element CE and the electric element EE onto a circuit board CB to provide a module M. The number of circuit elements is not limited to one electric element or to one electric component. The circuit board CB can comprise further circuit elements for an external circuit configuration of the electric element EE. The end portions of the leads that protrude from the cooling element CE can be mechanically and electrically connected to corresponding counterparts at or in the circuit board CB. To avoid a disturbance of the electric functionality via the cooling element CE, the cooling element CE does not provide any short circuit between signal or power conduction elements, e.g. leads L, and connections of the ground potential of the circuit board CB or of the electric element EE.

Further, the circuit board CB can be attached to a base plate BP. Heat of the electric element can be transferred via the cooling element CE to the circuit board CB and then to the base plate BP for further heat dissipation.

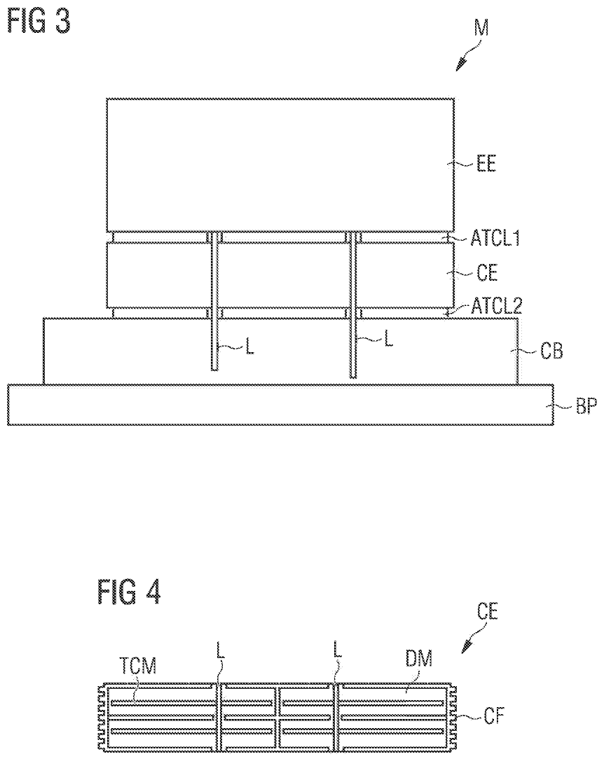

As shown in FIG. 3, the thermal coupling between the electric element EE and the cooling element CE can be further improved by providing a first additional thermal conduction layer ATCL1. Further, the thermal coupling between the cooling element CE and the circuit board CB can be improved by providing a second additional thermal conduction layer ATCL2. The first and/or the second additional thermal conduction layer ATCL1, ATCL2 can be realized by a thermal paste pads. Of course the thermal paste pads should be electrically isolated from the leads L to prevent short circuit if the materials of the additional thermal conduction layer comprise electrical conducting material.

FIG. 4 illustrates a possible internal construction of the cooling element CE. Specifically, the cooling element CE comprises a dielectric material DM that is an electrical insulator. Further, the cooling element CE comprises holes via which the leads L of the electric element can connect an external circuit environment. Further, the cooling element CE comprises two or more thermal conduction layers TCM that are thermally coupled to the leads L but that are electrically isolated from a ground potential of the cooling element CE. The cooling element CE can comprise one thermal conductivity layer TCM, dielectric material DM or electrical conductive material without multi layers.

The cooling element CE can have an electrically conducting material at its outer sides that provide a ground potential of a circuit board to the electric element EE. Specifically, the outer metal of the cooling element CE can be thermally coupled to ground connections such as ground vias of the circuit board. Thus, the dielectric material DM must maintain an electrical separation between the leads L and the thermal conduction layers TCM that are coupled, e.g. connected, to the leads L on one side and ground structures of the cooling element CE on the other side. On the side surface area the cooling element can be connected with short distance vias, connecting electrically conductive layers of top and bottom surface. For the vias, special thermal vias, which lead the thermal better from top surface to bottom surface layer can be applied.

Further, it is possible that the cooling element has cooling fins CF at its side surfaces.

FIG. 5 shows a possible electrical connection between the leads L of the electric element EE of the component and corresponding conduction patterns CP e.g. for power supply or signal supply in the circuit board CB. To that end, the circuit board can comprise holes. Further, the circuit board CB can comprise ground vias GND via which a good thermal coupling between the cooling element, specifically the underside of the cooling element, and a corresponding base plate BP is provided.

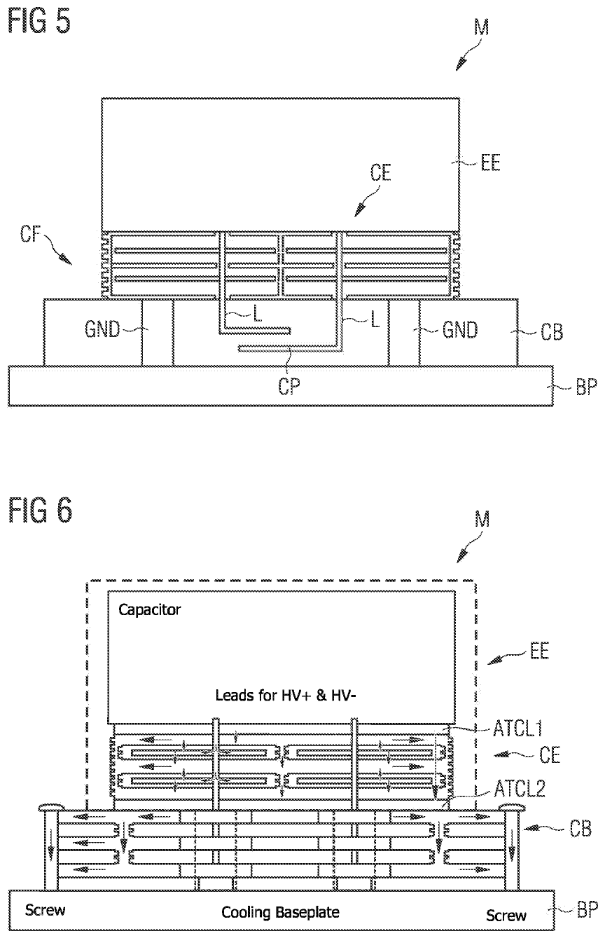

FIG. 6 illustrates possible internal structures of the cooling element CE and of the circuit board CB and corresponding heat flow path. Specifically, the heat flows in a variety of parallel segments from the bottom side of the electric element EE and from the leads to the circuit board CB. The circuit board CB is mounted via screws at a cooling base plate and the screws provide an additional heat flow for dissipating the heat in the base plate. Holes are provided within the circuit board CB to house the leads connected to the electric element EE. The leads can be used for applying a high voltage signal HV+, HV−.

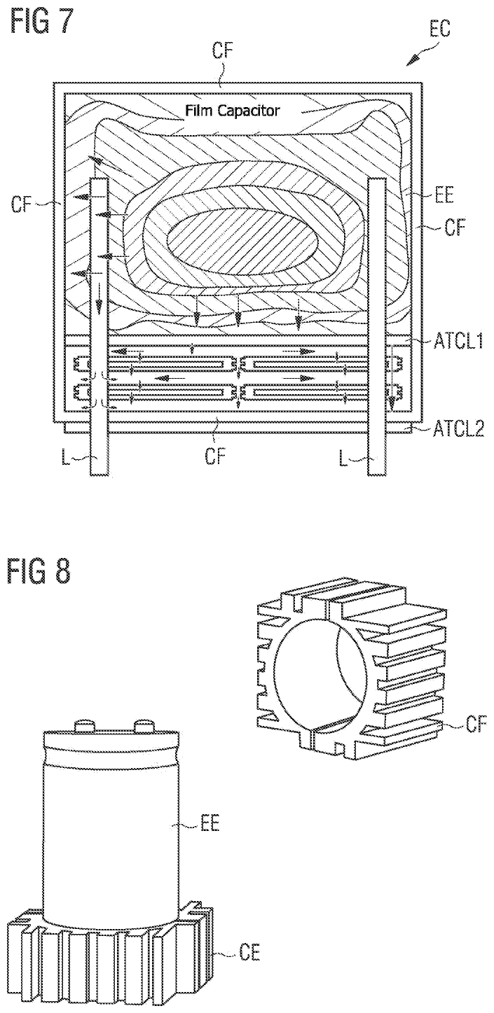

FIG. 7 shows the possibility of arranging one or more metallic films as cooling material, which can consist of aluminum or copper; or cooling fins CF at the side surfaces, at the top surface and at the underside of the electric component EC to reduce operation temperatures. These metallic films can be cooled actively or via additional thermal conduction layers ATCL at the bottom of the electric element EE. Again, the broad arrows indicate the heat flow paths used for dissipating heat.

FIG. 8 illustrates a perspective view of a capacitor as an electric element EE on a cooling element CE having cooling fins at its side surfaces. Further, cooling fins CF of the side surfaces of the electric element EE are shown in the upper right part of FIG. 8 to illustrate that the cooling fins can be removably applied.

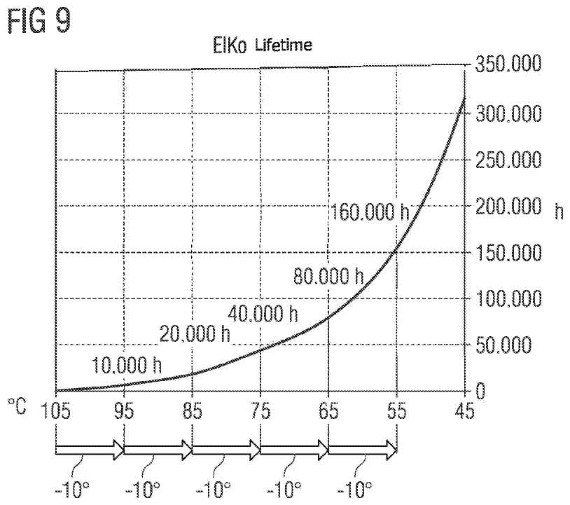

FIG. 9 illustrates the lifetime of an electrolytic capacitor (ELKO). Specifically, a reduction of 10 K leads to an increase of lifetime by the factor of 2. Thus, a six fold 10 K temperature decrease results in an increase of the lifetime from 5000 hours to 320000 hours.

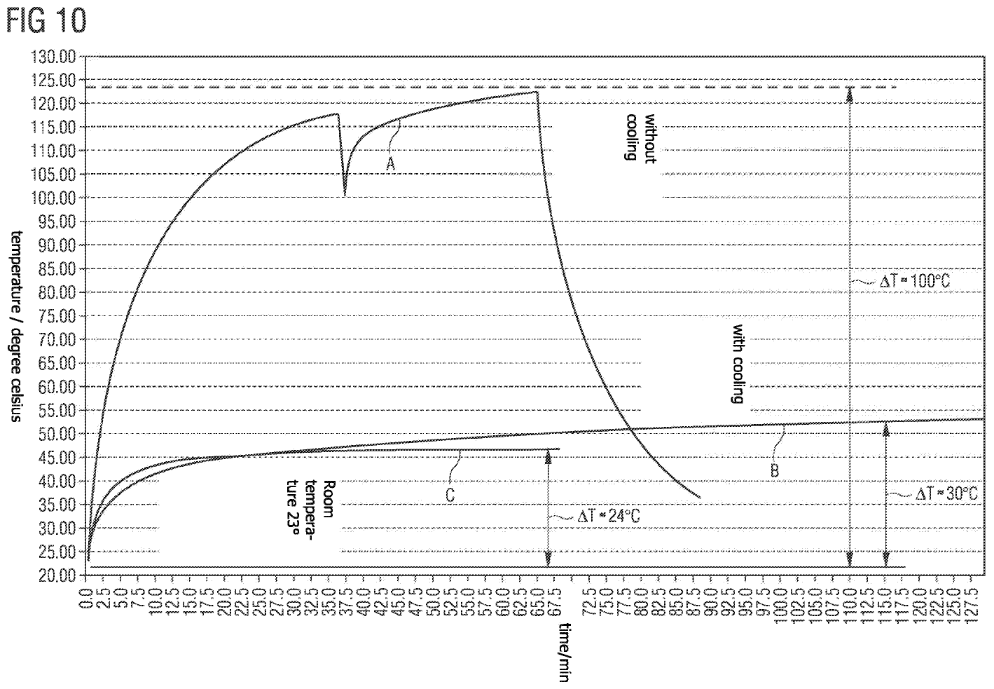

FIG. 10 shows the operation temperature for a given operation time after activation. Specifically, curve B illustrates the thermal behaviour of an electric element coupled via a cooling element to a circuit board. Curve C illustrates the thermal behaviour of an electric element coupled via a cooling element to a circuit board that comprises water cooling. Curve A shows the thermal behaviour without a cooling element. It can be seen that after an operation time of 67 minutes, even when switched off for a short period of time, the electric element without a cooling element has an operation temperature that is 70 Kelvin higher than the operation temperatures of the electric elements with a cooling element. Thus, as a temperature reduction of 10 K results in doubling the lifetime, a substantial increase in lifetime is obtained via the cooling element CE.

Neither the cooling element nor the module are limited by the number of technical features stated above. The electric component and the corresponding module can comprise further circuit elements to establish an electrical circuit for a given functionality. Further, the provision of active cooling fins or the use of Peltier elements for further cooling is also possible.

1.-17. (canceled)

18. An electric component comprising:
an electric element with an underside and a lead at the underside; and
a cooling element comprising an underside,
wherein the cooling element is arranged below the electric element, and
wherein the cooling element is a heat bridge configured to conduct heat from the underside of the electric element to the underside of the cooling element and/or from the lead to the underside of the cooling element.

19. The electric component of claim 18, wherein a footprint of the cooling element is smaller than or equal to a footprint of the electric element.

20. The electric component of claim 18, wherein the cooling element has a layered structure.

21. The electric component of claim 20, wherein the layered structure comprises a high thermal conduction layer and a dielectric layer, and wherein a thermal conductivity of the high conduction layer is larger than a thermal conductivity of the dielectric layer.

22. The electric component of claim 21, wherein the high thermal conduction layer comprises a material selected from group consisting of a crystalline material, a ceramic material, alumina (Al₂O₃), a metal, gold, silver, copper, aluminum nitride (AlN), and beryllium oxide (BeO).

23. The electric component of claim 21, wherein the dielectric layer comprises a dielectric material selected from the group consisting of a crystalline material, a ceramic material, Al₂O₃, an organic material, a PCB material, FR4, and FR-408.

24. The electric component of claim 18, wherein the lead comprises an electrically conducting material selected from a metal, gold, silver, or copper.

25. The electric component of claim 18, further comprising a top and a side and one or more cooling fins arranged at the top and/or at the side.

26. The electric component of claim 18, further comprising one or more cooling fins arranged at a side, wherein the one or more cooling fins are arranged at a side of the electric component and/or at the side of the cooling element.

27. The electric component of claim 18, further comprising a first additional thermal conduction layer arranged between the electric element and the cooling element and/or a second additional thermal conduction layer arranged at the underside of the cooling element.

28. The electric component of claim 27, wherein the first and/or second additional thermal conduction layers comprise a material select from the group consisting of a thermal solid and a liquid paste.

29. The electric component of claim 18, wherein the electrical element is selected from the group consisting of a passive circuit element, a capacitance element, a paper, a film, a ceramic capacitance element, an electrolyte capacitor, a Y-glass capacitor, a resistance element, a diode, a sensor, an active circuit element, a switch, an element with an integrated circuit, a processor, a semiconductor element and a light-emitting diode (LED).

30. The electric component of claim 18, wherein a height of the cooling element is larger than or equal to 0.1 mm and smaller than or equal to 5 mm.

31. The electric component of claim 18, wherein the cooling element has a layered structure with up to 9 stacked layers.

32. The electric component of claim 18, wherein the cooling element comprises a thermal conduction layer (TCM), a dielectric material and/or an electrically conductive material in a single layer construction.

33. A module comprising:
a circuit board; and
the electric component of claim 18,
wherein the cooling element of the electric component or a second additional thermal conduction layer is arranged on the circuit board.

34. The module of claim 33, further comprising a ground via in the circuit board thermally coupled to the underside of the cooling element.

35. The module of claim 33, further comprising a base plate, wherein the circuit board is arranged at the base plate.
